(19) United States
(12) Patent Application Publication
(10) Pub. No.: US 2002/0177300 A1
(43) Pub. Date: Nov. 28, 2002

(54) Method for forming an opening in polymer-based dielectric

(76) Inventors: Hsueh-Chung Chen, Taipei Hsien (TW); Tong-Yu Chen, Hsinchu (TW); Chih-Chien Liu, Taipei (TW); Chingfu Lin, Taipei (TW)

Correspondence Address: J.C. Patents, Inc., Suite 250, 4 Venture, Irvine, CA, 92618, US

(21) Appl. No.: 10/155,569

(22) Filed: May 24, 2002

(30) Foreign Application Priority Data
May 25, 2001 (TW) 90112584

(51) Int. Cl. H01L 21/4763

(52) U.S. Cl. 438/637

(57) ABSTRACT

A method for forming a damascene opening in a polymer-based dielectric layer is introduced. The method includes providing a substrate, which has also a conductive structure layer and a polymer-based dielectric layer formed thereon already. The polymer-based dielectric layer is uniformly hardened by a thermal treatment. A mask layer is formed on the polymer-based dielectric layer. The mask layer and the polymer-based dielectric layer are patterned to form an opening. The opening exposes a surface of the polymer-based dielectric layer. The exposed surface of the polymer-based dielectric layer is further hardened by a local hardening process. The local hardening process includes using an irradiation source of a high energy light beam, electron beam or ion beam to proceed the local hardening. The irradiation source can be incident onto the substrate by vertical angle or inclining angle. The substrate can also be rotated.

### CROSS-REFERENCE TO RELATED APPLICATION

This application claims the priority benefit of Taiwan application serial no. 90112584, filed May 25, 2001.

### BACKGROUND OF THE INVENTION

1. Field of the Invention

The present invention relates to semiconductor fabrication. Particularly, the present invention relates to a method for forming a damascene opening in a polymer-based dielectric layer.

2. Description of the Related Art

Typically, in dual damascene technology, metal wiring and vias that are connected to the previous wiring are formed in a dielectric layer by using dry etching process. It is that a dielectric layer is first formed on a substrate. The dielectric layer usually is also planarized. Then, according to the desired structure of the metal wiring and the interconnection to connect to the other level of metal wiring, the dielectric layer is etched to form a dual damascene opening including the vertical via opening and the horizontal metal wiring trench. A conductive layer is deposited over the substrate to fill the via opening and the metal wiring trench of the dual damascene opening. Then, the conductive layer is planarized by a chemical mechanical polishing (CMP) process, so as to remove a top portion of the conductive layer above the dielectric layer. The remaining portion fills the via opening and metal wiring trench, and accomplish the dual damascene interconnect, where the via plug and the metal wiring are formed at the same time. This is a typical dual damascene process.

In the foregoing descriptions, silicon oxide is the most commonly used dielectric material in the semiconductor fabrication process above 0.13 micron technology nodes. As the dimension of semiconductor device reaches to sub-0.13 micron nodes, low-k dielectric material is required to reduce the RC delay for high speed semiconductor devices. However, silicon oxide having a dielectric constant k greater than about 4.2 is no longer suitable for high speed applications.

FIGS. 1A-1B are cross-sectional drawing, illustrating a typical opening formed in a dielectric layer. In FIG. 1A, a conductive structure layer 102 has been formed on a substrate 100. Then, a dielectric layer 104, such as a silicon oxide layer, is formed over the substrate 100 and covers the conductive structure layer 102.

In FIG. 1B, a hard mask layer 106 is formed on the dielectric layer 104. Using photolithography and etching processes, the hard mask layer 106 and the dielectric layer 104 are patterned to form a dual damascene opening 108 and/or the line trench 110. The dual damascene opening 108 includes the lower portion of the via opening and the upper portion of the line trench. The via opening is used for connection with the conductive structure layer 102 and the line opening is used to form the metal wiring. After filling the via opening and the trench, the interconnect structure can be formed.

The opening structure of the dual damascene opening 108 is a good design as device integration increases. However, as the device integration greatly increases, the dielectric material of high dielectric constant also generates parasitic capacitance in the interconnect structure, inducing high RC effect resulting in defects of the device. One way to reduce the parasitic capacitance is taking the low-k materials. Even though some low-k dielectric materials, such as polymer-based dielectric material, are known in the art, their hardness is insufficient to achieve the necessary mechanical strength in the interconnect structure. The polymer-based dielectric materials in conventional manner still cannot effectively replace the dielectric material of high dielectric constant. Particularly to the fabrication process of 0.13 micron technology nodes or less, the polymer-based dielectric material in the current technology still has no wide applications.

### SUMMARY OF THE INVENTION

The invention provides a method for forming a damascene opening in a polymer-based dielectric layer, which has sufficient mechanical strength to hold the interconnect structure. The polymer-based dielectric layer is treated by a thermal process, so as to uniformly harden the polymer-based dielectric layer. After the opening is formed, a local hardening process is performed to further harden the peripheral surface of the opening, so that the necessary mechanical strength for the interconnect structure is achieved.

The invention provides a method for forming a damascene opening in a polymer-based dielectric layer. The method includes providing a substrate, which has also a conductive structure layer and a polymer-based dielectric layer formed thereon already. The polymer-based dielectric layer is uniformly hardened by a thermal treatment. A mask layer is formed on the polymer-based dielectric layer. The mask layer and the polymer-based dielectric layer are patterned to form an opening. The opening exposes a surface of the polymer-based dielectric layer. The exposed surface of the polymer-based dielectric layer is further hardened by a local hardening process.

In the foregoing descriptions, the local hardening process includes using at least one irradiation source, which includes an energetic light, an electron beam or an ion beam, to locally harden the exposed surface of the polymer-based dielectric layer within the opening. The at least one irradiation source can irradiate the polymer-based dielectric layer in vertical incident direction or a slant incident direction. The substrate can also be rotated.

The present invention provides an opening structure in a polymer-based dielectric, and the opening structure is formed on a substrate. A polymer-based dielectric layer hardened by thermal effect is located on the substrate, wherein the polymer-based dielectric layer has an opening to expose a surface of the polymer-based dielectric layer. A mask layer covers the polymer-based dielectric layer at a portion other than the opening. A polymer-based surface layer with local hardening treatment is located on the exposed surface of the polymer-based dielectric layer within the opening.

In the invention, the polymer-based dielectric layer with the thermal treatment is the main body of the dielectric layer. The exposed surface by the opening has the polymer-based surface layer with local hardening treatment, so that the polymer-based dielectric layer has sufficient mechanical strength to hold the interconnect.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A through 1B are cross-sectional drawings, illustrating the conventional process for fabricating an opening in a dielectric layer; and

FIGS. 2A through 2E are cross-sectional drawings, schematically illustrating the process for fabricating an opening in a polymer-based dielectric, according to the invention.

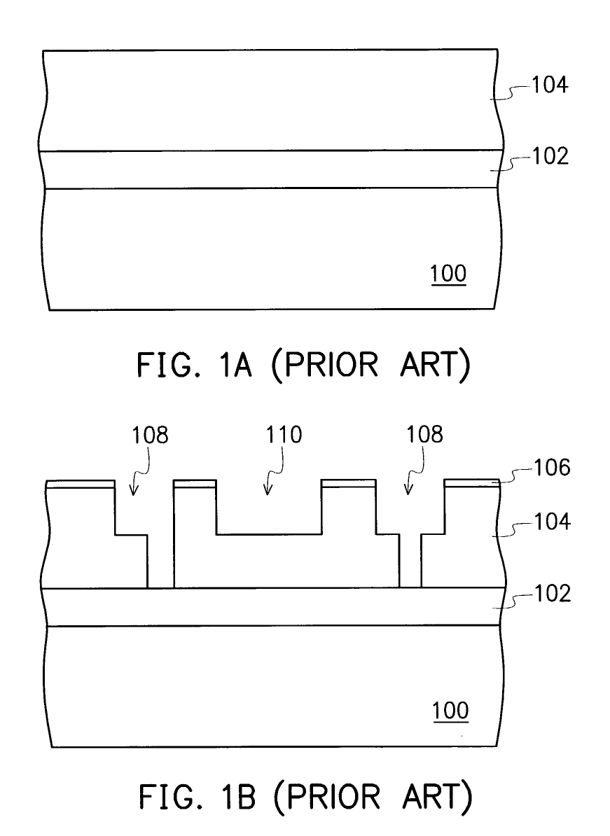

### DESCRIPTION OF THE PREFERRED EMBODIMENTS

The invention uses the polymer-based dielectric material as a dielectric layer to replace the conventional dielectric layer with high dielectric constant. However, due to the insufficient hardness of the polymer-based dielectric material, a thermal process is performed to uniformly harden the polymer-based dielectric layer. Then, a portion of surface of the polymer-based dielectric layer is further locally hardened by energetic light, electron beam, or ion beam.

In general, the polymer-based dielectric material can be hardened by a thermal treatment through, for example, a furnace or a heating plate. In this manner, the polymer-based dielectric material can be uniformly hardened. After the thermal treatment on a polymer-based dielectric layer, the polymer-based dielectric layer can be patterned to form the desired opening. At this stage, the mechanical strength is still insufficient. A local hardening treatment is then additionally performed on the exposed surface of the polymer-based dielectric layer within the opening to reinforce the mechanical structure of the opening. In the following, an example is provided for descriptions.

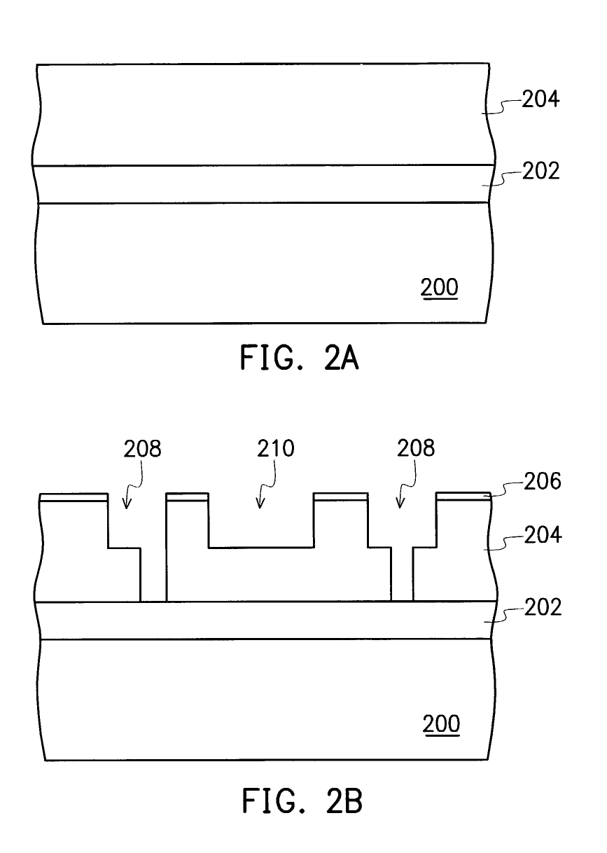

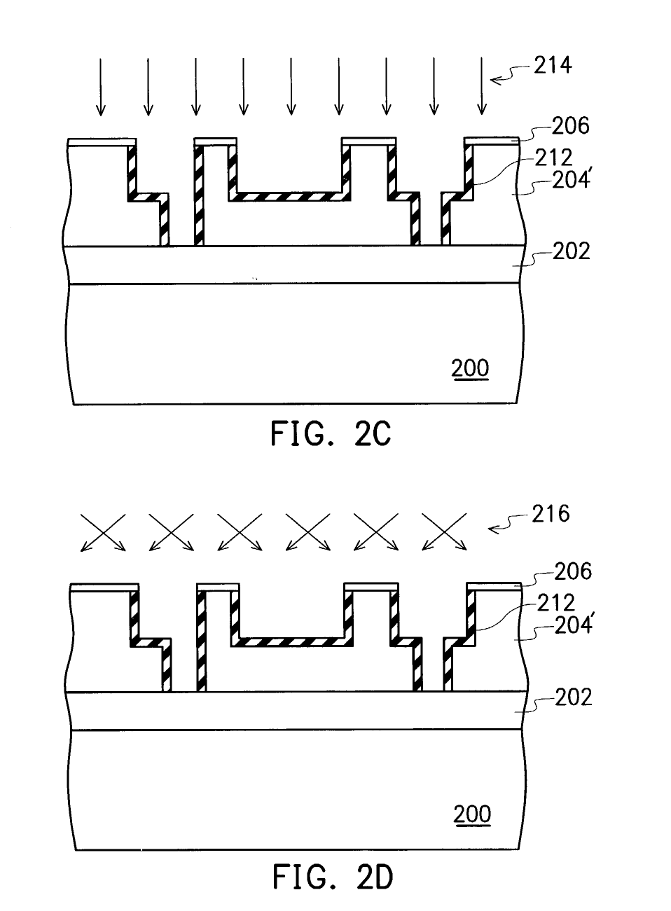

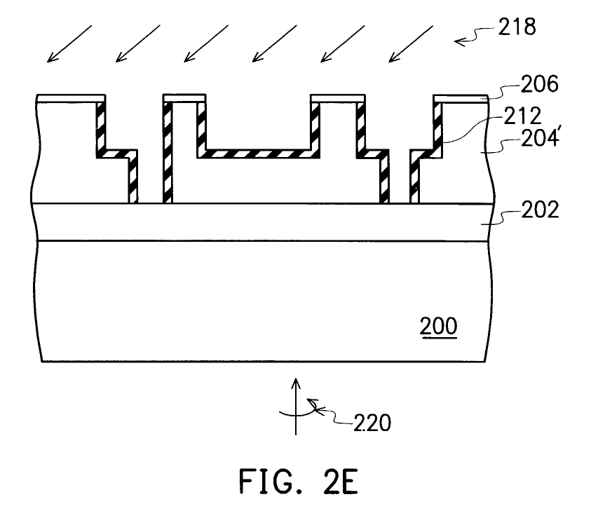

FIGS. 2A through 2E are cross-sectional drawings, schematically illustrating the process for fabricating an opening in a polymer-based dielectric, according to the invention. In FIG. 2A, a substrate 200 is provided. The substrate 200 can be a semiconductor substrate with a device (not shown) already formed thereon or a conductive structure layer 202, such as an interconnect structure, formed on top of the substrate 200. A polymer-based dielectric layer 204 is formed on the substrate 200 and also covers the conductive structure layer 202. At the current stage, the polymer-based dielectric layer 204 has poor hardness. A thermal treatment through a furnace or a heating plat is performed to uniformly harden the polymer-based dielectric layer 204 in the first stage.

In the conventional method as previously mentioned, the polymer-based dielectric layer may be hardened by irradiating energetic light thereon, such as ultra violet source or laser beam. The polymer-based dielectric layer can also be hardened by, for example, electron beam or ion beam. However, it is not easy to obtain a uniform hardness of the whole polymer-based dielectric layer by using the energetic light, electron beam or ion beam. This causes the difference of hardness in the polymer-based dielectric layer. Therefore, the irradiating hardening process can only achieve the effects of local hardening. The irradiating hardening process by only itself is not suitable for hardening the polymer-based dielectric layer. However, the invention particularly combines the thermal hardening process and the irradiating process to enhance the hardness of the polymer-based dielectric layer 204.

In FIG. 2B, after the polymer-based dielectric layer 204 has be treated by thermal hardening process, the uniform hardness has allowed to be patterned by photolithography and etching processes, so as to form the desired openings, such as contact opening, via opening, trench, or dual opening. The desired type of opening can be formed in the polymer-based dielectric layer 204 by the conventional manner. In FIG. 2B, the dual damascene opening 208 and the trench 210 are only shown as an example for descriptions. The dual damascene opening 208 includes a lower portion of via opening that exposes the conductive structure layer 202. Moreover, the mask layer 206 can also be included for the patterning process to form the opening. The patterning process with technologies of photolithography and etching to form the opening is well known by skilled artisan. The details are not further described. The patterning process to form the opening in the polymer-based dielectric layer 204 is direct relation. The invention is compatible with any kind of patterning processes for forming the opening.

Even though the polymer-based dielectric layer 204 is uniformly hardened by the thermal hardening process, the opening may still be destroyed due to insufficient hardness of the polymer-based dielectric layer 204. The invention continuously uses the local hardening process to reinforce the peripheral surface of the polymer-based dielectric layer 204 within the opening, thereby the opening has sufficient mechanical strength. In FIG. 2C, an irradiating source 214 is incident to the substrate 200 alone an incident direction about being vertical to the substrate surface. In this manner, the opening peripheral surface of the polymer-based dielectric layer 204 exposed by the openings 208, 210 are irradiated by the irradiation source 214, whereby a polymer-based irradiated layer 212 is formed thereon. A portion of the polymer-based dielectric layer 204 without being irradiated now is indicated by the numeral reference number of 214′.

Moreover, the irradiate source 214 shown in FIG. 2C is not the only option. Various options are shown in FIG. 2D and FIG. 2E. In FIG. 2D, multiple irradiating sources 216 are included, such as two irradiating sources. Each of the irradiating sources 216 is incident onto the substrate 200 respectively with an angle. In FIG. 2D, the two irradiating sources are respectively incident onto the substrate 200 by a slant angle. Another arrangement is also shown in FIG. 2E. In FIG. 2E, the irradiating source is set by a slant angle, but the substrate 200 is rotating following a rotation mechanism 220. In this manner, the sidewall of the openings 208, 210 can be effectively irradiated.

The method of the invention can be generally applied to opening formation in a polymer-based dielectric layer, particularly to the process for forming the dual damascene structure in the polymer-based dielectric layer.

The invention allows the polymer-based dielectric with low dielectric constant to be used as the dielectric layer, thereby the parasitic capacitance of the interconnect structure is effectively reduced.

The invention uses the thermal treatment to first uniformly harden the polymer-based dielectric, and then uses an irradiating manner to locally harden the exposed surface of the polymer-based dielectric.

The irradiating source used in the invention can include a single source or multiple sources. Each of the irradiating sources can irradiate the polymer-based dielectric by an individual incident angle, including an vertical incident or a slant incidence.

In the invention, while the polymer-based dielectric is irradiated, the substrate can also be rotated.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for forming an opening in polymer-based dielectric, the method comprising:
providing a substrate;
forming a polymer-based dielectric layer on the substrate;
performing a thermal process to harden the polymer-based dielectric layer;
patterning the polymer-based dielectric layer to form an opening, wherein the opening exposes a peripheral surface of the polymer-based dielectric layer; and
performing a local hardening process to further harden the exposed surface of polymer-based dielectric layer.

2. The method for forming an opening in polymer-based dielectric according to claim 1, wherein the step of patterning the polymer-based dielectric layer comprises forming a mask layer on the polymer-based dielectric layer, and the mask layer and the polymer-based dielectric layer are patterned together.

3. The method for forming an opening in polymer-based dielectric according to claim 1, wherein the opening comprises one selected from the group consisting of a via opening, a trench, and a dual damascene opening.

4. The method for forming an opening in polymer-based dielectric according to claim 1, wherein the step of performing a local hardening process comprises using an irradiating source to irradiate the exposed surface of the polymer-based dielectric layer.

5. The method for forming an opening in polymer-based dielectric according to claim 4, wherein the irradiating source comprises a light source with sufficient energy to harden polymer-based dielectric material.

6. The method for forming an opening in polymer-based dielectric according to claim 4, wherein the irradiating source comprises one selected from the group consisting of an ultra violet source and a laser beam.

7. The method for forming an opening in polymer-based dielectric according to claim 4, wherein the irradiating source comprises one selected from the group consisting of electron beam and ion beam.

8. The method for forming an opening in polymer-based dielectric according to claim 4, wherein the irradiating source comprises a single irradiating source, which is about vertically incident onto the substrate.

9. The method for forming an opening in polymer-based dielectric according to claim 4, wherein the irradiating source comprises a single irradiating source which is incident onto the substrate in a slant angle, while the substrate is rotating.

10. The method for forming an opening in polymer-based dielectric according to claim 4, wherein the irradiating source comprises at least two irradiating sources which are incident onto the substrate with incident angles, respectively.

11. The method for forming an opening in polymer-based dielectric according to claim 10, wherein the at least two irradiating sources includes two irradiating sources which are incident onto the substrate with slant incident angles, respectively.

12. The method for forming an opening in polymer-based dielectric according to claim 1, wherein in the step of providing the substrate, the substrate comprises a conductive structure layer formed thereon.

13. An opening structure in polymer-based dielectric, the opening structure comprising:
a substrate;
a thermal-hardening polymer-based dielectric layer formed over the substrate, wherein the thermal-hardening polymer-based dielectric layer has an opening that exposes an opening peripheral surface of the thermal-hardening polymer-based dielectric layer;
a mask layer formed on the thermal-hardening polymer-based dielectric layer at a portion other than the opening; and
a local-hardening polymer-based surface layer formed on the peripheral surface of the thermal-hardening polymer-based dielectric layer.

14. The opening structure in polymer-based dielectric according to claim 13, wherein the opening in the thermal-hardening polymer-based dielectric layer comprises one selected from the group consisting of via opening, trench, and dual damascene opening.

15. The opening structure in polymer-based dielectric according to claim 13, wherein the local-hardening polymer-based surface layer comprises a polymer-based surface layer hardened by ultra violet source.

16. The opening structure in polymer-based dielectric according to claim 13, wherein the local-hardening polymer-based surface layer comprises a polymer-based surface layer hardened by laser beam source.

17. The opening structure in polymer-based dielectric according to claim 13, wherein the local-hardening polymer-based surface layer comprises a polymer-based surface layer hardened by a light source.

18. The opening structure in polymer-based dielectric according to claim 13, wherein the local-hardening polymer-based surface layer comprises a polymer-based surface layer hardened by electron beam.

19. The opening structure in polymer-based dielectric according to claim 13, wherein the local-hardening polymer-based surface layer comprises a polymer-based surface layer hardened by ion beam.

20. The opening structure in polymer-based dielectric according to claim 13, wherein the substrate comprises a conductive structure already formed thereon.
